(19) United States
(12) Patent Application Publication
(10) Pub. No.: US 2025/0358579 A1
(43) Pub. Date: Nov. 20, 2025

(54) PROCESS FOR PRODUCING A PLURALITY OF MEMS TRANSDUCERS WITH ELEVATED PERFORMANCE CAPABILITY

(71) Applicant: Hahn-Schickard-Gesellschaft für angewandte Forschung e. V., Stuttgart (DE)

(72) Inventors: Alfons Dehé, Reutlingen (DE); Dennis Becker, Donaueschingen (DE)

(21) Appl. No.: 18/873,634

(22) PCT Filed: May 31, 2023
(86) PCT No.: PCT/EP2023/064511

§ 371 Date: Dec. 10, 2024

(30) Foreign Application Priority Data
Jun. 10, 2022 (EP) 22178294.9

(51) Int. Cl. H04R 31/00; B81B 3/00; B81C 1/00; H04R 7/12; H04R 19/02

(52) U.S. Cl. CPC H04R 31/003; B81B 3/0021; B81C 1/00158; H04R 7/122; H04R 19/02; B81B 2201/0257; B81B 2203/0127; B81B 2203/019; B81B 2207/012; B81C 2201/0132; B81C 2201/0133; B81C 2201/0194; H04R 2201/003

(57) ABSTRACT

The invention preferably relates to a method for producing a MEMS transducer comprising a membrane and a carrier, wherein the membrane exhibits a meander structure comprising vertical and horizontal sections. Here, a shaping component is first provided which is coated with a membrane layer system. The membrane layer system comprises at least one actuator layer comprising an actuator material. By structuring the membrane layer system, membranes are provided which can be attached to a carrier. The shaping component can be completely removed.

Furthermore, the invention preferably relates to a MEMS transducer which can be produced by means of the method.

The invention preferably relates to a method for producing a MEMS transducer comprising a membrane and a carrier, wherein the membrane exhibits a meander structure comprising vertical and horizontal sections. Here, a shaping component is first provided which is coated with a membrane layer system. The membrane layer system comprises at least one actuator layer comprising an actuator material. By structuring the membrane layer system, membranes are provided which can be attached to a carrier. The shaping component can be completely removed.

Furthermore, the invention preferably relates to a MEMS transducer which can be produced by means of the method.

### BACKGROUND AND PRIOR ART

Today, microsystems technology is used in many areas of application for the manufacture of compact, mechanical-electronic devices. The microelectromechanical systems (MEMS for short) that can be produced in this way are extremely compact (micrometer range) and at the same time offer outstanding functionality. MEMS transducers, such as MEMS loudspeakers or MEMS microphones, are also known from the prior art. Current MEMS loudspeakers are usually designed as planar membrane systems with vertical actuation of a vibratable membrane in the direction of emission. Excitation is achieved, for example, by means of piezoelectric, electromagnetic or electrostatic actuators.

An electromagnetic MEMS loudspeaker for mobile devices is described in Shahosseini et al. 2015. The MEMS loudspeaker exhibits a reinforcing silicon microstructure as a sound radiator, with the moving part suspended from a carrier via silicon mainsprings to enable large out-of-plane displacements using an electromagnetic motor.

Stoppel et al. 2017 reveal a two-way loudspeaker whose concept is based on concentric piezoelectric actuators. As a special feature, the vibrating membrane is not closed, but comprises eight piezoelectric unimorph actuators, each consisting of a piezoelectric and a passive layer. The outer woofers consist of four trapezoidal actuators fixed on one side, while the inner tweeters are formed by four triangular actuators connected to a rigid frame by one or more springs. The separation of the membrane is intended to allow an improved sound image with higher output.

A disadvantage of such planar MEMS loudspeakers is their limitation in terms of sound power, particularly at low frequencies. One reason for this is that the sound pressure level that can be generated is proportional to the square of the frequency for a given displacement. Therefore, sufficient sound power requires either deflections of the vibrating membranes of at least 100 μm or membranes with a large surface area in the square centimeter range. Both conditions are difficult to realize using MEMS technology. The difficulties are particularly evident in the context of possible production steps that cannot be implemented efficiently.

In the prior art, it was therefore proposed to design MEMS loudspeakers that do not exhibit a closed membrane for vibrations in the vertical emission direction, but rather a large number of movable elements that can be induced to vibrate laterally or horizontally. The advantage of this is that an increased volume flow can be moved on a small surface area and thus an increased sound power can be provided.

A MEMS loudspeaker based on this principle is disclosed, for example, in US 2018/0179048 A1 and Kaiser et al. (2019). The MEMS loudspeaker comprises a plurality of electrostatic bending actuators, which are arranged as vertical lamellae between a top and bottom wafer and can be induced to vibrate laterally by means of appropriate control. An inner lamella forms an actuator electrode opposite two outer lamellas. Apart from a connecting node of electrodes that are still galvanically separated, there is an air gap between the three curved lamellae. If a potential is applied from inside to outside, this leads to an attraction on both sides due to the curvature of the design in the direction of a preferred direction, which is specified by an armature. The bulges on the outer lamellae aid movability. The restoring force is provided by a mechanical spring force. Pull-push operation is therefore not possible.

Another disadvantage is that gaps between the bending actuators and the top/bottom wafers, which are necessary for their movability, lead to ventilation between the two chambers. This limits the lower cut-off frequency. Furthermore, the lateral movement of the bending actuators and therefore the sound power is restricted in order to avoid a pull-in effect and acoustic breakdown.

WO 2021/144400 A1 discloses a MEMS transducer that can be used both as a MEMS loudspeaker and as a MEMS microphone. The MEMS transducer described therein exhibits a vibratable membrane which is constructed in such a way that it comprises two or more vertical sections which are substantially parallel to the vertical direction. Furthermore, the vibratable membrane comprises at least one layer of an actuator material and is in contact with at least one electrode at its end. This allows the vertical sections to be induced to vibrate horizontally by activation of the electrode. Conversely, an electrical signal can also be generated at the electrode when the vertical sections are induced to vibrate horizontally.

The MEMS transducer disclosed in WO 2021/144400 A1 exhibits significant improvements over the prior art. In the case of a MEMS loudspeaker, the design of the vibratable membrane comprising the vertical sections advantageously leads to a higher sound power. In the case of a MEMS microphone, a higher performance and audio quality with a suitable sound image is also advantageously achieved. In addition, proven semiconductor processing methods can be used to produce the MEMS transducer, enabling cost-efficient production.

The MEMS transducer disclosed in WO 2021/144400 A1 is preferably produced by etching a substrate, preferably from a front side, to form a meander structure. At least two layers are then applied, wherein at least a first layer comprises an actuator material and a second layer comprises a mechanical support material, or at least two layers comprising an actuator material are coated. The first and/or the second layer are then placed in contact with an electrode.

With regard to the production process of the MEMS transducer disclosed in WO 2021/144400 A1, there is a need for optimization. In particular, the etching of the substrate, which provides a carrier for the vibratable membrane, is complex. The etching of the substrate is preferably carried out by DRIE etching, which is, however, cost-intensive. Furthermore, DRIE etching exhibits limitations with regard to the choice of sacrificial layers (stop oxides) and the possibility of achieving different depths during etching. An alternative method for providing a carrier by wet chemical KOH etching (potassium hydroxide) requires an enlarged spatial area, which leads to a larger installation space and is associated with losses in terms of the compactness of the MEMS transducer. Particularly when producing a plurality of MEMS transducers, the larger space required for the carrier frame between the individual MEMS transducers leads to less efficient use of the wafer and higher costs.

DE 102017115923 A1 discloses a method for producing a MEMS transducer with a structured membrane. Here, a negative form is provided by a substrate and optionally a sacrificial layer, by means of which the structure of the membrane can be predetermined. The substrate or the negative form exhibits recesses which correspond to wave peaks or wave troughs of the membrane. An electrically conductive layer and a piezoelectric layer are then deposited on the negative form such that a membrane is formed with a side complementary to the negative form. In further process steps, the membrane is placed in electrical contact with electrodes at wave peaks and wave troughs. To expose the membrane, part of the substrate and the optionally applied sacrificial layer are removed by etching on the back. The remaining part of the substrate forms a holder or carrier for the membrane.

EP 3218303 B1 discloses a method for producing a plurality of MEMS packages. The package exhibits a base structure with an embedded chip, a MEMS component and a cover structure. A fluid connection between the MEMS component and an environment of the package is provided through a through-hole. The structure of the package is well suited for batch production. For this purpose, a plurality of chips can be embedded in a base master structure and a plurality of MEMS components can be mounted on the base master structure. After covering the resulting arrangement with a cover master structure, a preform for a plurality of packages is obtained. By forming separating or cutting lines, the arrangement is singularized and a plurality of separate packages are obtained.

Neither DE 102017115923 A1 nor EP 3218303 B1, however, offer suggestions for improving the production process of a MEMS transducer with a folded membrane according to WO 2021/144400 A1 in order to avoid a complex rear-side etching process or to achieve a smaller space requirement.

In light of the prior art, there is therefore a need to provide improved or alternative methods for producing a MEMS transducer.

### OBJECTIVE OF THE INVENTION

The objective of the invention was to eliminate the disadvantages of the prior art. In particular, it was a task of the invention to provide a method for producing MEMS transducers which is characterized by high process efficiency and economy, exhibits a low susceptibility to errors, is easily scalable and ensures the production of MEMS transducers characterized by excellent acoustic properties and compact dimensions.

### SUMMARY OF THE INVENTION

The objective of the invention is solved by the independent claims. Advantageous embodiments of the invention are disclosed in the dependent claims.

In a first aspect, the invention relates to a method for producing at least one MEMS transducer for interacting with a volume flow of a fluid comprising
a carrier and
a membrane for generating or receiving pressure waves of the fluid in a vertical direction, which is held by the carrier,
   wherein the membrane exhibits a meander structure with vertical sections and horizontal sections, wherein the vertical sections are formed substantially parallel to the vertical direction and the horizontal sections connect the vertical sections to one another, wherein the membrane comprises at least one actuator layer of an actuator material and is in contact with at least one electrode, such that the vertical sections can be induced to vibrate horizontally by actuation of the at least one electrode, or such that an electrical signal can be generated at the at least one electrode when the vertical sections are induced to vibrate horizontally, characterized in that the method comprises the following steps:
a) provision of a shaping component,
b) coating the shaping component with a membrane layer system comprising at least the actuator layer, wherein the membrane layer system exhibits the meander structure comprising vertical sections and horizontal sections after coating on the shaping component,
c) provision of the membrane by structuring the membrane layer system,
d) complete removal of the shaping component,
e) attaching the membrane to the carrier such that the membrane is held by the carrier.

The inventors have recognized that the preferred method for producing a MEMS transducer achieves significant improvements in many aspects. In particular, the complete removal of the shaping component has a highly advantageous effect on both the efficiency of the production process and the MEMS transducer that can be produced.

Firstly, there is no need to use multiple etching processes to provide a carrier to which the membrane is attached for the purpose of generating or absorbing pressure waves.

Instead, a (temporary) shaping component (or molding component) is provided, which can be completely removed again after coating to form a membrane layer system. This represents a substantial difference compared to, for example, the method disclosed in WO 2021/144400 A1 for producing a MEMS transducer. The latter proposes structuring a substrate before coating it with a membrane layer system, wherein frame regions of the substrate form a carrier for the membrane. For this purpose, a starting substrate is etched from a front side, e.g. by DRIE etching, in order to provide a structure on the substrate that is congruent with the meander structure of the membrane. Coating processes are then carried out to apply the membrane layers and then the membrane is again exposed on the rear side in sections by means of further DRIE etching, wherein a frame of the substrate remains and forms the carrier. It is not possible to completely remove the rear side of the substrate using a simple etching process in the process design, as otherwise no carrier can be provided.

According to the invention, it was recognized that by attaching the membrane to a separate carrier, the shaping component can be dispensed with and complete (rear-side) removal is possible. The supposed disadvantage of providing a separate carrier is offset by a number of advantages, which are associated in particular with the possible complete removal of the shaping component.

This eliminates the need for a complex DRIE etching process to expose the rear side of the membrane. Instead, a (cost-effective) and highly selective wet chemical etching process can be used, for example. In this respect, advantageously, no separate grinding or sanding steps are required prior to DRIE etching.

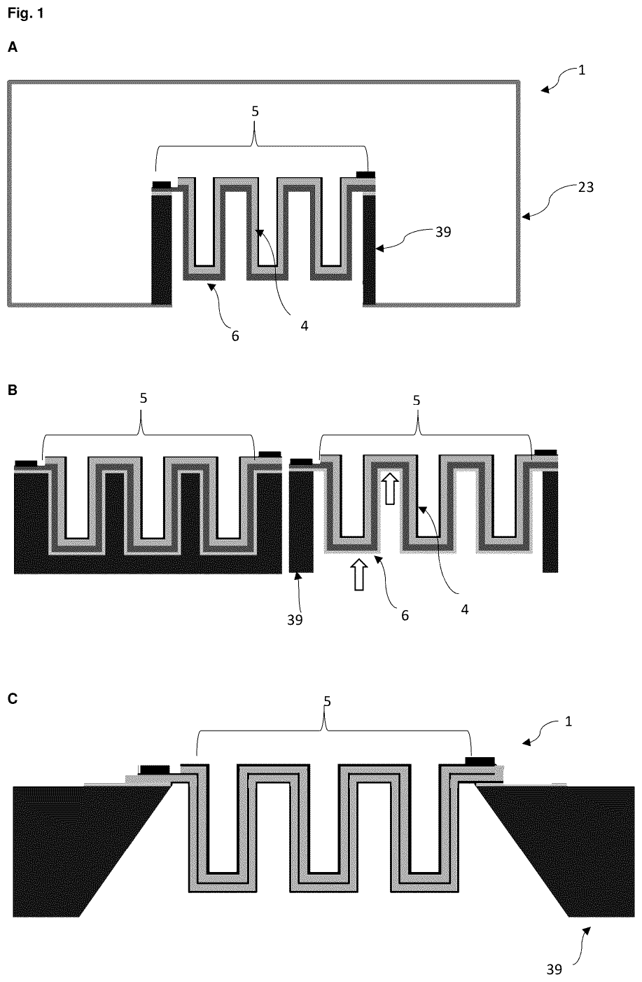

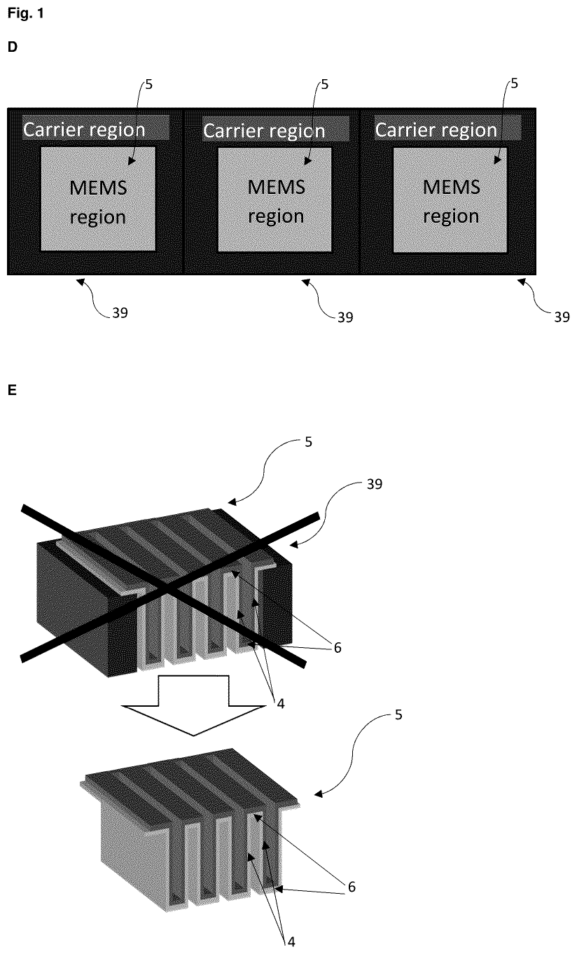

Since the shaping component is completely removed and no external carrier needs to remain, when producing a plurality of MEMS transducers, these can also be positioned extremely compactly on the wafer. It is not necessary to increase the spacing of the individual chips in order to take account of increased space requirements if a carrier is to remain as a frame in the case of KOH etching (see FIG. 1C, D). Dicing can also be dispensed with when producing a plurality of MEMS transducers on one wafer.

The solution according to the invention therefore advantageously saves time and costs, such that a higher number of MEMS transducers can be produced in a shorter time with less material.

The preferred method steps a)-e) are not restricted to the above sequence in order to achieve the advantages. Preferably, steps a)-e), depending on the embodiment, of the aspects according to the invention can be carried out, for example, overlapping in time, simultaneously or in a different order.

For example, after coating the membrane layer system on the shaping component, it may be preferred to structure it and connect it to a support structure, thereby enabling stabilization in order to reliably remove the shaping component completely. Advantageously, one method step, namely the complete removal of the shaping component, thus provides a plurality of membranes which are initially stabilized on a support structure, but can be transported from this to a carrier and attached. Thus, it may be preferred that step d), the complete removal of the shaping component, and step e), the attachment of the (individual) membranes to a respective carrier, are carried out after step c), structuring of the membrane layer system to provide individual membranes.

It may also be preferred that structuring of the membrane layer system to provide one or more membranes (step c) takes place after the membrane layer system has been attached to a carrier structure (step e). In this case, the attachment of the membrane layer system to a carrier structure also preferably takes place before the complete removal of the shaping components (step d), by which the individual membranes are provided. By attaching the membrane layer system to a carrier structure before the complete removal of the shaping component, a separate support structure can be dispensed with. After removal of the shaping component, individual membranes are provided on individual carriers by separating the carrier structure in certain regions.

The following explanations of the individual method steps therefore apply to different combinations of the sequence of the method steps and are not limited to the sequence selected for illustrative purposes.

In a first step, it may be preferred to provide the shaping component. Preferably, the shaping component is provided (structured) in such a way that on an accessible side, preferably a front side, a meander structure congruent with the desired meander structure of the membrane is present. The structure of the shaping component thus preferably determines the meander structure of the membrane. In other words, the shaping component can also be understood as a template or die for shaping the membrane layer system.

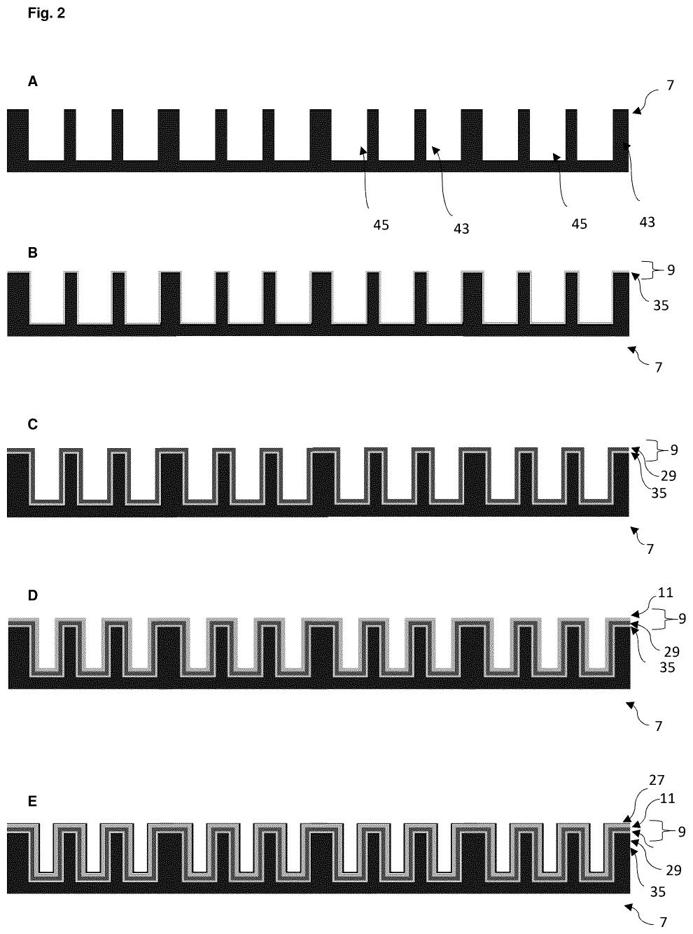

Preferably, the shaping structure exhibits a structure such that, after coating of the membrane layer system, a meander structure comprising vertical sections and horizontal sections is present. Preferably, the shaping component can be present as a comb structure substrate comprising comb fingers and empty regions, such that a membrane folded congruently with the comb structure can be provided when the membrane layer system is coated (see FIG. 2A). Preferably, the shaping structure forms a negative form for the membrane layer system and thus in particular for the membrane resulting from the membrane layer system. By coating the membrane layer system onto the shaping structure, the membrane layer system exhibits a geometric configuration that is congruent with the shaping structure.

The shaping structure can be provided by structuring a (semiconductor) substrate, for example by DRIE etching a substrate to create the comb fingers and empty regions for the comb structure substrate as a shaping structure. After the shaping component has been provided, the membrane layer system is preferably coated. The comb structure substrate preferably comprises a main strand, comb fingers and empty regions. The comb fingers refer to sections that are substantially orthogonal to the main strand and are separated from each other by the empty regions. The main strand can therefore be regarded as a support for the comb fingers. The empty regions preferably refer to sections in which there is no more substrate material. The comb structure substrate is preferably provided by an etching process. In this process, a (semiconductor) substrate is preferably etched starting from a front side, such that cavities are left on the substrate, wherein the cavities in turn form the empty regions, while the non-etched sections act as comb fingers.

The meander structure of the membrane can be configured in particular by the dimensions of the shaping component, e.g. as a comb structure substrate. For example, the length of the comb fingers of a comb structure substrate preferably corresponds to the length of the vertical sections of the membrane. The width of the comb fingers determines the width of horizontal sections that connect the vertical sections to each other at their (front) upper region. The width of the empty regions corresponds to the width of the horizontal sections that connect the vertical sections at their lower region. By providing a comb structure substrate in which the width of the comb fingers is equal to the width of the empty regions or intermediate areas, horizontal sections of equal length can preferably be ensured for the membrane.

In the context of the invention, the membrane layer system preferably refers to one or more layers which serve to provide the membrane of the MEMS transducer. In particular, the membrane layer system comprises a layer or stratum comprising an actuator material, which is referred to as an actuator layer, which is explained in more detail below and is used in particular for generating or detecting vibrations of the membrane. The terms “layer” and “stratum” can be used synonymously in the context of the invention. Preferably, the membrane layer system comprises further layers in addition to the actuator layer, in particular a top electrode, a bottom electrode and/or a mechanical support layer. Furthermore, the membrane layer system can preferably comprise a sacrificial layer, which is preferably first coated on the shaping component before the coating of further layers of the membrane layer system.

By simply structuring the membrane layer system, interruptions can preferably be provided which define end regions for the membranes that can be attached to the carrier. By coating the shaping component, a membrane layer system can thus advantageously be provided simultaneously for a plurality of membranes, the dimensions of which can be determined by the shaping component on the one hand and the structuring carried out later on the other hand. In other words, the structuring of the membrane layer system preferably comprises a formation of interruptions, whereby a singularization or separation of the membrane layer system into membranes takes place. In the context of the invention, the separated sections of the membrane layer system obtained by structuring are preferably already designated as a membrane even before a shaping component is removed and/or the membranes are attached to a carrier.

A membrane is thus preferably formed from the membrane layer system by structuring, wherein the membrane is preferably already present when it is still applied to the shaping component or has not yet been exposed. By completely removing the shaping component and attaching the membrane to a carrier, the membrane is exposed and a vibrational capability is ensured as a functional property of the membrane for the MEMS transducer. In its structural configuration, however, the membrane is preferably already present as a preform after the structuring of the membrane layer system.

Preferably, the membrane layer system is coated starting from a front side. The front side of the shaping component preferably refers to the side on which the shaping component exhibits a structure (for example a comb structure) on which the membrane layer system is to be formed by coating. Preferably, the shaping component is provided in such a way that it is correspondingly structured on the front side, while the shaping component is not structured on the rear side.

The complete removal of the shaping component is preferably carried out starting from a rear side of the shaping component. The rear side of the shaping component is therefore preferably the side facing away from the membrane layer system.

The membrane is preferably also attached to a carrier from the front side, such that the front side of the membrane in turn faces a sound opening in the carrier and thus preferably indicates a direction of sound emission or sound detection of the finished MEMS transducer.

Preferably, the shaping component is completely removed by means of a wet chemical etching process. Advantageously, this means that thinner sacrificial layers can be used than would be necessary with a DRIE etching process, for example, resulting in advantageous material savings. The use of wet chemical etching processes also means that there is a greater choice of material for the sacrificial layer, which also has a positive effect on cost-effectiveness.

In addition, there is increased design flexibility with regard to the configuration of the vertical and/or horizontal sections of the preferred MEMS transducer. In particular, any limitations associated with rear-side exposure of the membrane are eliminated, as wet chemical etching processes can be efficiently performed to completely remove the shaping component for any length and/or width of the vertical and/or horizontal sections.

In the context of the invention, the complete removal of the shaping component preferably means a removal in which no functional components of the shaping component (for example as carriers) remain. The average person skilled in the art knows that after a complete removal of the shaping component, it cannot be excluded that minor constituents still remain. However, it is preferred that the shaping component is substantially completely removed when the shaping component is completely removed.

Terms such as substantially, approximately, etc. preferably describe a tolerance range of less than ±40%, preferably less than ±20%, particularly preferably less than ±10%, even more preferably less than ±5% and in particular less than ±1% and in particular comprise the exact value. Similar preferably describes quantities that are approximately equal. Partial preferably describes at least 5%, particularly preferably at least 10%, and in particular at least 20%, in some cases at least 40%.

In contrast to the disclosure of DE 102017115923 A1 (or WO 2021/144400 A1), the shaping component is completely removed in the context of the invention. It is apparent from the teaching of DE 102017115923 A1 that a negative form for the membrane, which would be comparable to the shaping component, is only to be partially removed, such that a holder or carrier for the membrane is obtained after the partial removal. However, the method according to the invention deviates from the disclosure of DE 102017115923 A1 in particular due to the complete removal of the shaping component. In other words, in the context of the invention, a structural and functional decoupling of a shaping component and a carrier is provided. This preferably means that separate components are used to provide the structural configuration of the membrane and to provide a holder for the membrane. As described above, the inventors have recognized that by providing a separate shaping component and a carrier, various advantages are achieved with respect to the production process, which outweigh any disadvantages. On the one hand, a simpler and more cost-effective complete rear-side removal of the shaping component is possible. On the other hand, a wafer can be used particularly efficiently, especially in the case of producing a plurality of MEMS transducers. In the context of the invention, the shaping component is therefore not used as a carrier or a holder for the membrane in the finished MEMS transducer, but is preferably a (temporary) aid for the geometric shaping of the membrane and serves to apply the membrane layer system.

The membrane can preferably be attached to the carrier by transferring the membrane from a support structure to a carrier. As explained below, a mounting component can be used for this purpose, for example, which is suitable for removing (individual) membranes from the support structure and attaching them to a carrier on which, for example, a conductive adhesive is present for establishing a contact.

It may also be preferred for a carrier structure to be attached to the membranes and to the membrane layer system before the shaping component is removed. After removal of the shaping component, the carrier structure serves to stabilize the membrane(s) or the membrane layer system. An additional support structure is not necessary. By appropriately separating the carrier structure (with applied membranes or the membrane layer system), a plurality of MEMS transducers can therefore be obtained, wherein one membrane is held by each carrier. In the finished MEMS transducer, the carrier preferably serves both to suspend the membrane and to establish an electrical contact with the membrane. For this purpose, the carrier can preferably also exhibit vias, which can be used as such and/or as surrounding contacts in order to apply or detect electrical signals.

The process-related separation of the provision of a shaping component for shaping the membrane layer system or the membrane from a separate carrier to which the membrane is later attached means that there is greater freedom with regard to the selection or configuration of the carrier.

The preferred method therefore also has an advantageous effect on the MEMS transducer that can be produced as such. For example, producible membranes can be attached to a freely selectable carrier starting from the membrane layer system, for example after removal from a support structure or by separation from a carrier structure. Due to the increased flexibility with regard to the suspension of the end-side regions of the membrane on the carrier, or establishing their contact thereto, particularly compact MEMS transducers can be provided, the acoustic connection of which can also be optimized.

For example, it may be preferred to attach the membrane to a carrier via a conductive process material that both allows establishment of an electrical contact and forms an acoustic seal. In addition, depending on the dimensions of a preferred cover, the rear volume can be configured variably depending on the desired application. Advantageously, the preferred method can therefore provide a MEMS transducer that is particularly suitable in terms of acoustic requirements.

The design of the MEMS transducer that can be produced using this method combines the advantage of high sound power with simplified control.

In contrast to known planar MEMS loudspeakers, for example, the vibratable membrane itself does not have to be operated over a large area of multiple square centimeters or with deflections of more than 100 μm in order to generate sufficient sound pressure. Instead, the majority of the vertical sections of the vibratable membrane can move an enlarged total volume in the vertical emission direction with small horizontal or lateral movements of a few micrometers.

At the same time, simplified control can be achieved. Whereas in the prior art a plurality of piezoelectric actuators have to be placed in contact with the horizontal sections, the MEMS transducer described here can be operated by means of at least one electrode, preferably at the end. This reduces the production complexity, minimizes sources of error and also inherently entails synchronous control of the vertical sections to generate horizontal vibrations.

In this way, the air volumes present between the vertical sections can be moved extremely precisely along the vertical emission direction by the horizontal vibrations.

This also makes it possible to provide a particularly powerful MEMS microphone with high audio quality. The structure of the MEMS microphone is structurally similar to that of the MEMS loudspeaker, in particular with regard to the configuration of the vibratable membrane. However, instead of controlling the electrodes to generate horizontal vibrations and thus sound pressure waves, the MEMS microphone is configured to receive sound pressure waves in the same vertical direction. Preferably, there are volumes of air between the vertical sections, which are moved along a vertical detection direction when sound waves are received. The sound pressure waves induce the vertical sections to vibrate horizontally, such that the actuator material generates a corresponding periodic electrical signal that can be read out by an electronic circuit.

The term MEMS transducer therefore refers to both a MEMS microphone and a MEMS loudspeaker. In general, the MEMS transducer refers to a transducer for interacting with a volume flow of a fluid that is based on MEMS technology and whose structures for interacting with the volume flow or for receiving or generating pressure waves of the fluid exhibit dimensions in the micrometer range (1 μm to 1,000 μm). The fluid can be either a gaseous or a liquid fluid. The structures of the MEMS transducer, in particular the vibratable membrane, are configured to generate or receive pressure waves of the fluid.

For example, as in the case of a MEMS loudspeaker or MEMS microphone, these can be sound pressure waves. However, the MEMS transducer can also be suitable as an actuator or sensor for other pressure waves. The MEMS transducer is therefore preferably a device or apparatus that converts pressure waves (e.g. acoustic signals as alternating sound pressures) into electrical signals or vice versa (conversion of electrical signals into pressure waves, for example acoustic signals).

Applications of the MEMS transducer as an energy harvester are also possible, wherein pneumatic or hydraulic alternating pressures are used. In these cases, the electrical signal can be discharged as recovered electrical energy, stored or fed to other (consumer) devices.

A MEMS loudspeaker preferably refers to a loudspeaker that is based on MEMS technology and whose sound-generating structures are at least partially dimensioned in the micrometer range (1 μm to 1000 μm). Preferably, for example, the vertical sections of the vibratable membrane can exhibit a dimension in the range of less than 1000 μm in width, height and/or thickness. It may also be preferred, for example, that only the height of the vertical sections is dimensioned in the micrometer range, while the length may have a larger dimension and/or the thickness a smaller size.

A MEMS microphone preferably refers to a microphone that is based on MEMS technology and whose sound-receiving structures at least partially exhibit dimensions in the micrometer range (1 μm to 1000 μm). Preferably, for example, the vertical sections of the vibratable membrane can exhibit a dimension in the range of less than 1000 μm in width, height and/or thickness. It may also be preferred, for example, that only the height of the vertical sections is dimensioned in the micrometer range, while the length may have a larger dimension and/or the thickness a smaller size.

Preferably, the MEMS transducer comprises the vibratable membrane for generating or receiving pressure waves of the fluid in a vertical direction. The vibratable membrane thus refers to the structure that makes it possible to generate an electrical signal after pressure waves have been received or to generate pressure waves by applying an electrical signal. For this purpose, it is preferred that the vibratable membrane exhibits at least one actuator layer made of an actuator material. Preferably, the vibratable membrane is structured in such a way that it exhibits a meander structure comprising vertical and horizontal sections.

A meander structure preferably refers to a structure formed from a sequence of substantially orthogonal sections in cross-section. The mutually orthogonal sections are preferably vertical and horizontal sections of the vibratable membrane. It is particularly preferred that the meander structure is rectangular in cross-section. However, it may also be preferable for the meander structure to exhibit a sawtooth shape (zig-zag shape) in cross-section or to be curved or undulating. This is particularly the case if the vertical sections are not aligned exactly parallel to the vertical emission or detection direction, but include an angle of ±30°, preferably ±20°, particularly preferably ±10° with the vertical direction.

In preferred embodiments, the horizontal sections may also not be at an exact orthogonal angle of 90° to the vertical emission or detection direction, but may, for example, include an angle between 60° and 120°, preferably between 70° and 110°, particularly preferably between 80° and 100° with the vertical direction.

Preferably, the vertical and/or horizontal sections are rectilinear at least in sections or over their entire length, but the vertical and/or horizontal sections can also be curved at least in sections or over their entire length. In the case of a curved or undulating shape of the vertical and/or horizontal sections of the vibratable membrane in cross-section, the alignment preferably refers to a tangent to the vertical and/or horizontal sections at their respective centers.

The corresponding shape of the membrane(s) can be ensured by configuring the shaping component as described above.

While the vibratable membrane is preferably aligned horizontally to the sound emission direction or sound detection direction, the sound waves are generated or detected by actuation of the vertical sections.

Preferably, the layer of an actuator material in the vertical sections serves as a constituent of a mechanical bimorph, wherein a lateral curvature of the vertical sections is caused by controlling the actuator layer via the electrode or wherein a corresponding electrical signal is generated by an induced lateral curvature. A bimorph preferably refers to a structure that comprises two layers, wherein a displacement and/or curvature is made possible by the interaction of the two layers.

The meander structure preferably corresponds to a membrane folded along its width. For the purposes of the invention, a vibratable membrane can therefore preferably also be referred to as a bellows. The parallel folds of the bellows preferably form the vertical sections. The connecting sections between the folds preferably form the horizontal sections. Preferably, the vertical sections are longer than the horizontal sections, for example by a factor of 1.5, 2, 3, 4 or more. The horizontal sections preferably denote those structures that enable a connection between two or more vertical sections.

The performance of the MEMS transducer, in particular a MEMS loudspeaker or MEMS microphone, can be significantly determined by the number and/or dimensions of the vertical sections.

In preferred embodiments, the vibratable membrane comprises more than 3, 4, 5, 10, 15, 20, 30, 40, 50, 100 or more vertical sections.

In further preferred embodiments, the vibratable membrane comprises less than 10000, 5000, 2000 or 1000 or fewer vertical sections.

The preferred number of vertical sections leads to high sound power levels on the smallest chip surfaces without compromising the sound image or audio quality.

Preferably, the vertical sections are planar, which means in particular that their extension in each of the two dimensions (height, width) of their surface is greater than in a dimension perpendicular to this (the thickness). For example, size ratios of at least 2:1, preferably at least 5:1, 10:1 or more may be preferred.

In the context of the invention, the height of the vertical sections preferably corresponds to the dimension along the direction of sound emission or sound detection, while the thickness of the vertical sections preferably corresponds to the sum of the layer thickness of the one or more layers forming the vertical sections. The length of the vertical sections preferably corresponds to a dimension orthogonal to the height or thickness. In the cross-sectional views of the figures shown below, the height and thickness are shown schematically (not necessarily true to scale), while the dimension of the length corresponds to a (non-visible) drawing depth of the figures.

In a preferred embodiment, the height of the vertical sections is between 1 μm and 1000 μm, preferably between 10 μm and 500 μm. Intermediate ranges from the aforementioned ranges may also be preferred, such as 1 μm to 10 μm, 10 μm to 50 μm, 50 μm to 100 μm, 100 μm to 200 μm, 200 μm to 300 μm, 300 μm to 400 μm, 400 μm to 500 μm, 600 μm to 700 μm, 700 μm to 800 μm, 800 μm to 900 μm or even 900 μm to 1000 μm. A person skilled in the art will recognize that the aforementioned range limits can also be combined to obtain further preferred ranges, such as 10 μm to 200 μm, 50 μm to 300 μm or even 100 μm to 600 μm.

In a preferred embodiment, the thickness of the vertical sections is between 100 nm and 10 μm, preferably between 500 nm and 5 μm. Intermediate ranges from the aforementioned ranges may also be preferred, such as 100 nm to 500 nm, 500 nm to 1 μm, 1 μm to 1.5 μm, 1.5 μm to 2 μm, 2 μm to 3 μm, 3 μm to 4 μm, 4 μm to 5 μm, 5 μm to 6 μm, 6 μm to 7 μm, 7 μm to 8 μm, 8 μm to 9 μm or even 9 μm to 10 μm. A person skilled in the art will recognize that the aforementioned range limits can also be combined to obtain further preferred ranges, such as 500 nm to 3 μm, 1 μm to 5 μm or even 1500 nm to 6 μm.

In a preferred embodiment, the length of the vertical sections is between 10 μm and 10 mm, preferably between 100 μm and 1 mm. Intermediate ranges from the aforementioned ranges may also be preferred, such as 10 μm to 100 μm, 100 μm to 200 μm, 200 μm to 300 μm, 300 μm to 400 μm, 400 μm to 500 μm, 500 μm to 1000 μm, 1 mm to 2 mm, 3 mm to 4 mm, 4 mm to 5 mm, 5 mm to 8 mm or even 8 mm to 10 mm. A person skilled in the art will recognize that the aforementioned range limits can also be combined to obtain further preferred ranges, such as 10 μm to 500 μm, 500 μm to 5 μm or even 1 mm to 5 mm.

With the aforementioned preferred dimensions of the vibratable membrane or the vertical sections, a particularly compact MEMS transducer, in particular a MEMS loudspeaker or MEMS microphone, can be provided, which simultaneously combines high performance with excellent sound image or audio quality. Advantageously, the aforementioned dimensions can be achieved particularly easily by designing the shaping component accordingly. Preferably, the structure of the shaping component determines the structure of the vibratable membrane comprising vertical and horizontal sections.

The directional indications vertical and horizontal (or lateral) preferably refer to a preferred direction in which the vibratable membrane is oriented for generating or receiving pressure waves of the fluid. Preferably, the vibratable membrane is suspended horizontally between at least two regions of a carrier, while the vertical direction (direction of interaction with the fluid) for generating or receiving pressure waves is orthogonal to it. In the case of a MEMS loudspeaker, the vertical (interaction) direction corresponds to the vertical sound emission direction of the MEMS loudspeaker. In this case, vertical preferably means the direction of sound emission, while horizontal means a direction orthogonal thereto. In the case of a MEMS microphone, the vertical (interaction) direction corresponds to the vertical sound detection direction of the MEMS microphone. In this case, vertical preferably means the direction of sound detection or receiving, while horizontal means a direction orthogonal thereto.

In a further preferred embodiment, the method is characterized in that a plurality of MEMS transducers is produced, wherein for production of the plurality of MEMS transducers the membrane layer system is structured on the shaping component to form individual membranes, wherein particularly preferably the individual membranes are separated by interruptions, which are preferably formed as a whole after the coating of the membrane layer system or layer by layer.

The increased process efficiency of the method is demonstrated in particular by the possibility of efficiently producing a large number of MEMS transducers, preferably starting from a shaping component or a substrate as shaping component. A plurality of MEMS transducers preferably means 2, 3, 4, 5, 10, 20, 50, 100, 500, 1000 or more MEMS transducers.

The plurality of MEMS transducers can preferably be provided by means of a shaping component, wherein a membrane layer system is preferably first applied to the structured front side of the shaping component. Subsequently, the membrane layer system can be (laterally) structured by forming interruptions to define the individual membrane. An interruption preferably refers to a region in which one or more (preferably all) layers of the membrane layer system are removed. Particularly preferred are linear interruptions, which were made on the comb fingers when the shaping component was formed as a comb structure. The interruptions are therefore present in the region of horizontal sections of the membrane, which connect the vertical sections at the front end. The interruptions are preferably substantially linear in shape and are characterized by a narrow line width. Preferably, the interruptions exhibit line widths of less than 50 μm, preferably less than 30 μm, 20 μm, 10 μm, 5 μm, 2 μm or even less than 1 μm.

The interruptions can be used to determine the dimensions and/or number of individual membranes that are to be formed from the membrane layer system.

Particularly preferably, an array of membranes can be defined by the corresponding formation of interruptions, wherein the extent of the array is determined by the dimensions of the shaping component. For example, it may be preferred to form a correspondingly dimensioned array of membranes on a structured shaping component with square dimensions in a range from 10 mm to 500 mm. For a width and length of a membrane of 1 mm each, an array of 10×10 up to 500×500 membranes can be formed, depending on the size of the shaping component.

The interruptions can be formed using known means of the prior art, for example by etching processes. In this case, the interruptions can be made in their entirety after the coating of the membrane layer system, wherein a plurality of (preferably all) layers of the membrane layer system are structured in a single step. It may also be preferred for the interruptions to be formed layer by layer. This means that after the coating of one layer of the membrane layer system in each case, lateral structuring is carried out immediately by selective removal of the layer at the interruptions to be formed.

Advantageously, the membranes can be formed in an extremely space-efficient manner on the shaping component using only thin linear interruptions, such that the provision of a plurality of membranes and a corresponding plurality of MEMS transducers requires very little material.

In a further preferred embodiment, the method is characterized in that the shaping component is provided by an application of a dry etching process and/or a wet chemical etching process to a substrate, wherein preferably the dry etching process is a physical, a chemical and/or a physico-chemical dry etching process, wherein particularly preferably the dry etching process is selected from a group comprising reactive ion etching (RIE) and/or deep reactive ion etching (DRIE), wherein preferably KOH etching is used as the wet chemical etching process.

In semiconductor technology and microsystems technology, dry etching refers to a group of ablative microstructure processes that are not based on wet chemical reactions (such as wet chemical etching). The material is removed either by accelerated particles or with the aid of plasma-activated gases. Chemical, physical or physico-chemical effects are utilized, depending on the process.

Reactive ion etching (RIE) is an ion-assisted reactivity process. Due to the good controllability of the etching behavior, RIE is a process for the production of topographic structures for micro, semiconductor and nanosystem technology. The process allows both isotropic (direction-independent) and anisotropic etching through physico-chemical ablation. Etching is carried out using charged particles (ions) generated in a gas plasma. A corresponding masking (e.g. produced by photolithography) of the surface gives the structures their shape. For example, cavities and thus empty regions can be formed on a substrate by masking, wherein the non-etched sections can represent comb fingers of a comb structure substrate as a shaping component.

Deep reactive ion etching (DRIE) is a further development of reactive ion etching (RIE) and a highly anisotropic dry etching process for the production of microstructures in substrates with an aspect ratio of up to 50:1, wherein structure depths of a few 100 micrometers can be achieved. The DRIE process is a two-stage, alternating dry etching process in which etching and passivation steps alternate. The aim is to etch as anisotropically as possible, i.e. directionally perpendicular to the substrate surface. In this way, for example, very narrow cavities or recesses can be etched. Advantageously, for example, particularly narrow comb fingers and/or empty regions of the comb structure substrate are present as shaping components, which can be converted into narrow vertical and/or horizontal sections of the membrane(s).

Wet chemical etching is preferably carried out using a liquid reactant. This can be a chemical that dissolves the shaping component to be etched or a chemical mixture that first oxidizes the shaping component and then dissolves the oxide. Preferably, the reactant can be a stronger acid, e.g. hydrofluoric acid for a silicon substrate, or a weaker acid, e.g. citric acid for a gallium arsenide substrate. In the context of the invention, KOH etching has proven to be particularly advantageous for providing the shaping component. Advantageously, wet chemical etching processes can be carried out quickly, such that high etching rates can be achieved and the process time of the preferred method is reduced. Advantageously, a high degree of selectivity can also be achieved with simple means for carrying out the wet chemical etching process, e.g. with baths and/or wet chemical sprays.

The aforementioned etching processes are known to the person skilled in the art and can advantageously be used in preferred embodiments of the method. In particular, the aforementioned etching processes are suitable for providing a structure for forming the shaping component on a substrate which is congruent with the meander structure of the membrane, wherein the meander structure preferably results after coating the shaping component with the membrane layer system.

Depending on the desired structure of the shaping component, recesses can be made in a provided substrate in order to obtain a desired meander structure of the membrane. It is advantageously possible to choose etching processes that ensure efficient implementation and optimum shaping of the membrane layer system. For example, potassium hydroxide (KOH etching) exhibits a clear preference for etching along a <110> orientation (notation for Miller indices) of a silicon crystal versus a <111> orientation. Etching rates can thus be selected to enable particularly rapid provision of the shaping component.

In a further preferred embodiment, the method is characterized in that the shaping component comprises a material selected from a group consisting of monosilicon, polysilicon, silicon dioxide, silicon carbide, silicon germanium, silicon nitride, nitride, germanium, carbon, gallium arsenide, gallium nitride, indium phosphide and glass. Preferably, the shaping component is formed by structuring a substrate. The structuring can, for example, lead to a comb-structured substrate as the shaping component, wherein the structuring is preferably carried out using etching processes. Preferably, the material of the shaping component is a semiconductor material, such that a semiconductor substrate (wafer) can be used to structure it and thus provide the shaping component. The average person skilled in the art knows that the terms “wafer” and “(semiconductor) substrate” can be used synonymously.

The above materials are particularly easy and inexpensive to process in semiconductor and/or microsystem technology and are also well suited for mass production. These materials are also particularly well suited for doping and/or coating in order to obtain a desired intermediate stable connection with the membrane layer system and/or to enable optimum, substantially complete removal. The preferred aforementioned materials of the shaping component offer multiple advantages due to the usability of standardized process technologies.

The structuring and dimensions of the shaping component are selected according to the desired number and dimensions of the membranes. The shaping components can, for example, exhibit a characteristic extension (e.g. diameter, length and/or width) in a range between 10 mm and 500 mm, while a thickness or height (largest extension orthogonal to the surface) in a range between 100 μm and 1000 μm. A comb structure is introduced as explained above with corresponding dimensions to form a desired membrane with a meander structure, wherein a plurality of membranes can be provided on one shaping component due to the macroscopic extension in the surface.

In a further preferred embodiment, the method is characterized in that the shaping component is completely removed by a wet chemical etching process, wherein the wet chemical etching process is preferably selected from a group comprising KOH etching and/or TMAH etching.

Advantageously, by using a wet chemical etching process, thinner sacrificial layers can be used such that the material of the sacrificial layers is saved and thus the process efficiency of the preferred method is improved. Furthermore, the wet chemical etching process can be carried out in a simple and controlled manner, such that a reliable complete removal of the shaping component is ensured. Advantageously, the wet chemical etching process is highly selective, such that the risk of undesired etching processes, damage and/or possible contamination is reduced to a minimum.

In addition, advantageously, there is no need to carry out multiple dry etching processes and/or physico-chemical etching processes, such as DRIE etching, which are time-consuming and cost-sensitive. The single execution of a wet chemical etching process therefore achieves a considerable increase in process efficiency.

In the wet chemical etching process, the chemical bonds of the shaping component are preferably broken by etching media and converted into soluble constituents. KOH and/or TMAH etching have proven to be particularly suitable etching processes in the context of the invention.

In KOH etching, potassium hydroxide (KOH) is preferably used in solution to substantially completely remove the shaping component. In TMAH etching, a solution comprising tetramethylammonium hydroxide (TMAH) is preferably used. Both wet chemical etching processes advantageously exhibit excellent selectivity with regard to the choice of material for the sacrificial layer and/or shaping component.

In further preferred embodiments, the shaping component is completely removed by a dry etching process, wherein preferably the dry etching process is a physical, a chemical and/or a physico-chemical dry etching process, wherein particularly preferably the dry etching process is selected from a group comprising reactive ion etching (RIE) and/or deep reactive ion etching (DRIE).

It may also be preferred that the shaping component is completely removed by a vapor etching process (etching by using an etchant as a vapor or as a gas). For example, xenon difluoride vapor etching (XeF₂ vapor etching) can be carried out as a vapor etching process. Advantageously, isotropic xenon difluoride vapor etching is associated with a high degree of selectivity for (semiconductor) substrates, especially for silicon.

The aforementioned etching processes for the complete removal of the shaping component can be carried out individually or in combination with each other.

In a preferred embodiment, the method is characterized in that after structuring the membrane layer system, a plurality of membranes are connected to a support structure by means of a detachable connection.

A connection with the support structure can advantageously achieve the stability for the membrane(s) that is required after the complete removal of the shaping component. In particular, the support structure advantageously ensures that the meander structure of the membranes is retained and reduces the risk of loss of shape. Since the support structure itself is not part of the MEMS transducer, but merely serves to temporarily stabilize the membranes, the support structure can be selected in particular from a cost perspective. For example, the support structure can be made of a flat plastic substrate or a foil, preferably an adhesive foil. In principle, a wide variety of materials and geometric shapes are suitable for the support structures, provided that they can guarantee sufficient stability for the membranes and are also suitable for a detachable configuration of the connection.

The detachable connection of the membranes to the support structure is used for the subsequent transfer of the membrane(s) to the carriers, wherein, as explained below, a mounting component can be used, for example.

Preferably, the detachable connection is present in such a way that it is applied along the interruptions of the membrane layer system and thus the end regions of the individual membranes. The detachable connection can preferably be a decomposable connection, such that the membranes can be removed from the membrane layer system free of any damage.

For example, the detachable connection may be an adhesive, preferably a UV adhesive. A UV adhesive refers to an adhesive that hardens by irradiation with UV rays. UV adhesives can be detached, for example, by adding heat, i.e. a thermal effect and/or by using appropriate solvents. Preferably, a UV adhesive comprises epoxy resin and/or acrylate. The detachable connection can also be a thermally and/or chemically detachable adhesive. Thermally detachable adhesives can, for example, be selected from a group comprising wood glues, elastomers and/or silicone adhesives. Chemically detachable adhesives, i.e. adhesives whose connection can be detached by the use of a chemical solution, may comprise, for example, polyurethane.

In a preferred embodiment, the method is characterized in that the membrane is removed from a support structure by a mounting component, wherein the membrane is attached to the carrier preferably after removal of the membrane from the support structure.

The mounting component preferably refers to an apparatus that makes it possible to remove the membrane from the membrane layer system or from the support structure after the shaping component has been completely removed. The mounting component can, for example, be configured to apply a low pressure such that the membrane is detached from the detachable connection or the support structure by a pressure difference. In further embodiments, a porous chuck and/or a push needle can also be used. Preferably, a porous body is used, for example a porous ceramic material, wherein the low pressure is applied through the pores of the porous body. A desired suction force is generated by a preferably substantially uniform distribution of the pores and/or the pore size, while at the same time ensuring that the meander structure of the membrane retains its shape. Advantageously, this can achieve a particularly reliable removal of the membrane from the membrane layer system. It may also be preferred to use a pick-and-place tool for the mounting component.

In particular, the aforementioned preferred mounting components have proven to be particularly reliable in order not to impair the shape of the filigree components of the membrane during transportation from the support structure to the carrier. In addition, the preferred mounting components, such as a pick-and-place tool, can simultaneously support the detachment process, for example by heating in the case of a thermally detachable adhesive. It is also understood that it may also be preferred to transport a corresponding plurality of membranes from a support structure to the respective carriers at the same time with a plurality of mounting components. The mounting components can be dimensioned accordingly in order to reduce the production time, in particular through parallel processing.

Preferably, the membrane is attached to the carrier after it has been removed from the support structure. Preferably, this can be done directly by means of the mounting component, such that after the membrane has been removed, it can be attached to the carrier in a continuous process sequence. Advantageously, this avoids complex processing steps in order to establish a contact between the membrane and the carrier. Instead, the preferred method provides the option of using the mounting component to ensure an automated sequence of membrane removal and precise attachment to the carrier.

In a preferred embodiment, the method is characterized in that the membrane is attached to the carrier via a conductive process material, wherein preferably the conductive process material is selected from a group comprising a conductive adhesive or a conductive solder material.

The carrier is preferably a structure that has a substantially continuous border such that the membrane can be positioned stably at end regions. The carrier as such is preferably stable and rigid, such that sufficient strength is provided.

Preferably, the carrier exhibits one or more openings, which function in particular as sound inlet openings or sound outlet openings.

The term “sound inlet opening” is preferably used in embodiments in which the MEMS transducer is used as a MEMS microphone. The sound passes through the sound inlet opening to the membrane, which is induced into vibrations by the sound waves. A signal generated in this way, which indicates the incoming sound, can preferably be read out by means of an electronic circuit, which is also located on the carrier.

The term “sound outlet opening”, on the other hand, is preferably used in embodiments in which the MEMS transducer is used as a MEMS loudspeaker. The sound is emitted from a vibrating membrane into the environment through the sound outlet opening, wherein the vibrations of the membrane are preferably generated by an electronic circuit.

A conductive process material is preferably introduced in order simultaneously to enable a mechanical and an electrical connection between the carrier and the membrane. The conductive process material can preferably be applied to end regions of the membrane before the membrane is positioned on the carrier. The end regions of the membrane refer in particular to lateral regions of the membrane, such that the membrane is preferably connected to the carrier along its border. The conductive process material can also preferably be applied to the carrier first, in order to subsequently attach the membrane to the carrier. The membrane is preferably attached to the front of the carrier. This means that contact is established between the carrier and the membrane at the lateral regions, in particular starting from a front side of the membrane, i.e. the side of the membrane which was facing away from the shaping component in the membrane layer system and which points in the direction of the sound emission or sound detection in the completed MEMS transducer.

Preferably, the conductive process material is present on the carrier or the membrane as a closed ring in order to enable optimum attachment of the membrane to the carrier and an acoustic closure of the membrane at lateral (or horizontal) sections.

A conductive process material is preferably an electrically conductive process material. The process material advantageously ensures a reliable, stable and long-lasting connection between the membrane and the carrier. In particular, both an acoustic closure and establishment of an electrical contact between the membrane (or in particular its actuator position) and a preferred electronic circuit are also advantageously enabled. For example, electrical connections, e.g. wire bonding, can be present between an electronic circuit and the conductive process material.

Preferably, the conductive process material is selected from a group comprising a conductive adhesive, a conductive solder material or a conductive bonding material. The preferred material options for the conductive process material ensure both acoustic closure and an electrical contact. In addition, a conductive adhesive or solder material can be used to obtain a flexible connection that facilitates the vibration behavior of the membrane. Furthermore, the preferred materials are durable and ensure a long service life for the MEMS transducer.

In a further preferred embodiment, the method is characterized in that the carrier is connected to a cover, wherein the cover preferably exhibits a cover opening.

The cover preferably refers to a solid and, in particular, protective casing for the MEMS transducer. In particular, the cover serves to protect the components of the MEMS transducer from foreign material and/or damage. Thus, the cover extends substantially over preferred components of the MEMS transducer, for example over the membrane, electrical connections and/or an electronic circuit. The cover is preferably positioned on the rear side of the membrane carrier.

Furthermore, a rear volume of the MEMS transducer can be configured by dimensioning the cover accordingly. This makes it easy to adapt the acoustic performance of the MEMS transducer to the desired applications.

Preferably, the cover exhibits a cover opening. Advantageously, the acoustic properties of the MEMS transducer can be further optimized by providing the cover opening on the cover. In particular, the introduction of a cover opening leads to an increase in the effective rear volume.

Preferably, there are mounting regions on the cover to connect the carrier to the cover. Conventional methods known in the prior art can be used, such as soldering and/or gluing. Various mounting options and methods are within the knowledge of the skilled person and will not be described in detail.

In a further preferred embodiment, the method is characterized in that after structuring the membrane layer system, a plurality of membranes are connected to a carrier structure and the shaping component is then completely removed.

The carrier structure preferably refers to a structural preliminary stage for the provision of one or more carriers. The carrier structure is preferably already characterized by structural components which a carrier for the membrane preferably exhibits, e.g. one or more sound inlet or sound outlet openings, vias and/or electronic circuits. The carrier structure can therefore preferably be understood as an array of carrier elements which are (still) contiguous in the carrier structure and form the carriers by means of separation.

Preferably, the carrier structure exhibits dimensions that enable it to be fitted precisely to the membrane layer system, wherein it is particularly preferred that one carrier element is in contact with each membrane to be formed.

Preferably, the carrier structure also exhibits sufficient stability to ensure that the meander structure of the membranes or the membrane layer system is maintained during the complete removal of the shaping component. Preferably, the shaping component is only completely removed after the carrier structure has been connected to the membrane layer system.

The carrier structure can preferably be attached after structuring of the membrane layer system and thus separation of the membrane layer system to form membranes with the incorporation of interruptions as explained above. Preferably, the carrier structure is connected to the membrane layer system via a conductive process material at the position of the interruptions in the membrane layer system, which correspond to the end regions of the membranes to be formed.

In a further preferred embodiment, the method is characterized in that, after complete removal of the shaping component, a carrier structure is separated region by region such that, starting from the carrier structure, a plurality of carriers are provided and a membrane is attached to each of the plurality of carriers respectively.

Regional separation preferably means that the carrier structure is separated or cleaved off in sections. Since the carrier structure is preferably to be understood as a preliminary stage of one or more carriers, the regional separation preferably results in direct provision of the carriers on which the membranes are already suspended and with which the membranes are in electrical contact. Depending on the choice of carrier material, proven prior art technologies can be used for regional separation, which ensure precise and process-efficient implementation of the regional separation. For example, dicing may be preferred, which preferably comprises steps selected from scoring, breaking, sawing and/or (laser) cutting.

In preferred embodiments, a protective foil is attached to the carrier structure, the protective foil being present on the side opposite the membrane layer system and preferably extending at least over the region of the sound inlet or sound outlet openings, preferably over the entire surface of the carrier structure. The protective foil can provide protection for the carrier structure or the carriers to be formed during different processing steps, such as complete removal of the shaping components by etching or sectional separation of the carrier structure by dicing. Preferably, the protective foil can be used as a so-called dicing foil to provide an end point for sectional separation by dicing.

In a preferred embodiment, the method is characterized in that a carrier structure is connected to a plurality of covers, wherein the plurality of covers preferably exhibit a cover opening.

Preferably, the plurality of covers are applied in such a way that a precisely fitting cover is provided for each individual membrane on the interruptions of the structured membrane layer system or the end regions of the membrane. Preferably, the plurality of covers are applied before the regional separation of the carrier structure is carried out, thereby achieving parallel processing and increased efficiency. Similarly, the covers can also be applied after sectional separation of the carrier structure to form the individual carriers.

As explained above, the covers are preferably attached to the rear side of the carrier, wherein it may be preferred that the covers exhibit one or more cover openings to increase the rear volume.

The resulting MEMS transducer comprising a vibratable membrane, which is held by a carrier and is preferably protected on the rear side by a cover, can be removed from the protective foil by the preferred use of a mounting component and transported or prepared for further integration into a product.

In a further preferred embodiment, the method is characterized in that the membrane comprises at least two layers, wherein both layers comprise an actuator material and are each in contact with an electrode and the horizontal vibrations can be generated by a change in shape of one layer relative to the other layer or the horizontal vibrations lead to a change in shape of one layer relative to the other layer and generate an electrical signal.

In the embodiment, the horizontal vibrations are made possible by a relative change in shape of the two actuator layers. The actuator layers can consist of the same actuator material and be controlled differently. The actuator layers can also consist of different actuator materials, for example piezoelectric materials with different deformation coefficients. The actuator layers are to be understood here as part of the membrane layer system, which is preferably coated on the shaping component as described.

In the context of the invention, the “layer comprising an actuator material” is preferably also referred to as an actuator layer. An actuator material preferably means a material which undergoes a change in shape, for example elongation, compression or shear, when an electrical voltage is applied or, conversely, generates an electrical voltage when the shape is changed. Preferred are materials with electric dipoles, which undergo a change in shape when an electric voltage is applied, wherein the orientation of the dipoles and/or the electric field can determine the preferred direction of the changes in shape. Preferably, the actuator material can be selected from a group comprising a piezoelectric material, a piezoelectric polymer material and/or electroactive polymer (EAP).

In a further preferred embodiment, the method is characterized in that the membrane comprises at least two layers, wherein a first layer comprises an actuator material and a second layer comprises a mechanical support material, wherein at least the first layer comprising the actuator material is in contact with the electrode, such that horizontal vibrations can be generated by a change in shape of the actuator material relative to the mechanical support material or such that horizontal vibrations lead to a change in shape of the actuator material relative to the mechanical support material and generate an electrical signal.

In the context of the invention, the “layer comprising a mechanical support material” is preferably also referred to as a support layer. The mechanical support material or the support layer preferably serves as a passive layer which can resist a change in shape of the actuator layer. In contrast to an actuator layer, the mechanical support material preferably does not change its shape when an electrical voltage is applied. Preferably, the mechanical support material is electrically conductive such that it can also be used directly for establishing contact with the actuator layer. However, it can also be non-conductive in some embodiments and, for example, be coated with an electrically conductive layer.

The mechanical support material is preferably monocrystalline silicon, polysilicon or doped polysilicon.

When the actuator layer is actuated, it can undergo transverse or longitudinal stretching or compression, for example. This creates a stress gradient in relation to the mechanical support layer, which leads to a lateral curvature or vibration. This can be achieved, for example, by alternating the polarity of the electrodes, preferably by push-pull operation, whereby almost the entire air volume can be moved alternately between the vertical sections in the vertical emission direction.

While the actuator layer undergoes a change in shape when an electrical voltage is applied, the layer of the mechanical support material remains substantially unchanged. The resulting stress gradient between the two layers (mechanical bimorph) preferably causes a horizontal curvature. For this purpose, the thickness of the support layer relative to the thickness of the actuator layer should preferably be selected so that a sufficiently large stress gradient is generated for the curvature. For doped polysilicon as a mechanical support material and a piezoelectric material such as PZT or AlN, for example, thicknesses of substantially the same size, preferably between 0.5 μm and 2 μm, have proven to be particularly suitable.

Electrical contact can be established directly with the actuator layer and/or the layer made of a mechanical support material via electrodes at their ends, or electrical contact can be facilitated by a layer made of a conductive material, and thus an electrical voltage can be applied.

End-side positioning of the at least one electrode preferably means that contact with electronics, e.g. to a current or voltage source in the case of a MEMS loudspeaker, can be made at one end of the vibratable membrane, preferably at an end at which the membrane is suspended from the carrier. Electrode preferably means a region made of a conductive material (preferably a metal) which is configured for such contact with electronics, e.g. a current and/or voltage source in the case of a MEMS loudspeaker. Preferably, it can be a conductive adhesive material, soldering material or electrode pad. It is particularly preferred that the electrode is used to make contact with electronics and is itself connected to a conductive metal layer, which can extend over the entire surface of the vibratable membrane. In the following, the conductive layer together with its end-side contact with an electrode pad or a conductive process material is sometimes referred to as an electrode, for example as a top electrode or bottom electrode.

In a preferred embodiment, the method is characterized in that the membrane comprises three layers, wherein an upper layer is formed by a conductive material and functions as a top electrode, a middle layer is formed by an actuator material and a lower layer is formed by a conductive material and functions as a bottom electrode, wherein the conductive material of the upper and/or lower layer is preferably a mechanical support material.

Preferably, the top and/or bottom electrode is present as a layer of a conductive material, preferably metal, as a continuous or full-surface or contiguous layer of the vibratable membrane, which forms a substantially homogeneous surface and is not structured, in particular in the region of the individual membranes. Instead, the two or more vertical sections are preferably connected to end-side electrodes by means of an unstructured layer of a conductive material, preferably metal, such that the actuator layer can be actuated to induce the membrane to vibrate or a signal generated in the actuator layer can be read out by electronics on the carrier in the event of inducing the membrane by vibrations.

The designations top and bottom preferably refer to the position of the conductive material, such that in a cross-section it can be said that the top electrode comprises a conductive material above (or on the front side of) the actuator layer and the bottom electrode comprises a conductive material below (or on the rear side of) the actuator layer.

By means of the layer made of a conductive material, preferably metal, contact can advantageously be established between the two or more vertical sections and an end-side electrode or an electrode pad or conductive process material.

In further preferred embodiments, a layer of the conductive material can be formed from a support material such that, for example, a bottom and/or top electrode simultaneously acts as a mechanical support layer.

In an example embodiment, first a sacrificial layer is coated on a shaping component to form a membrane layer system, then a conductive material for the bottom electrode, which also serves as a support layer, followed by an actuator material to provide the actuator layer and then a further conductive material (which is not necessarily a support material) to provide the top electrode (see FIG. 2).

In a further preferred embodiment, the method is characterized in that the MEMS transducer exhibits an electronic circuit, wherein the electronic circuit exhibits an electrical connection with the membrane, wherein preferably the electronic circuit is mounted on the carrier.

Preferably, the electronic circuit is selected without limitation from a group comprising an integrated circuit (IC), an application specific integrated circuit (ASIC), a programmable logic circuit (PLC), a field programmable gate array (FPGA), a microprocessor, a microcomputer, a programmable logic controller and/or any other electronic circuit which is preferably programmable.

Depending on the use of the MEMS transducer, for example as a MEMS microphone or MEMS loudspeaker, the electronic circuit is intended to induce the membrane into vibrations (and thus to generate sound waves) and/or to detect vibrations of the membrane (due to excitation by incident sound waves).

In the case of a MEMS microphone, the electronic circuit preferably makes it possible to read out or detect an electrical signal that is generated when the sound pressure waves are incident on the membrane and the vertical sections are correspondingly induced into horizontal vibrations.

In the case of a MEMS loudspeaker, the electronic circuit is preferably configured to generate an electrical signal to induce the vertical sections into vibrations such that sound pressure waves are generated along a vertical emission direction.

Preferably, the electronic circuit is mounted on the carrier. In embodiments in which a carrier structure is used, one or more electronic circuits may be mounted on the carrier structure.

Advantageously, there is increased flexibility with regard to the choice of carrier in terms of design and electrical properties. In particular, the carrier can also function as a circuit carrier in addition to supporting the membrane. In particular, the conductive process material enables electrical contact between the membrane and conductive sections of the carrier, for example vias. In some embodiments, the producible MEMS transducer can be a bottom-port configuration.

In a further preferred embodiment, the method is characterized in that the carrier comprises a material selected from a group consisting of aluminum, ceramic, copper clad laminate (CCL) and/or glass fiber resin, wherein preferably the glass fiber resin is selected from a group comprising FR-4 or FR-5. Similarly, semiconductor materials can also be used as disclosed above for the shaping component. By separately providing a shaping component for shaping the membrane layer system or the membrane and a separate carrier to which the membrane is later attached, carrier materials can advantageously be selected which meet the requirements for mechanical stability, simple electrical contact and ensuring an optimum acoustic sound image, irrespective of the requirements for shaping the membrane.

The aforementioned preferred materials for the carrier have proven to be advantageous in that they enable a good connection between the membrane and the carrier. In particular, other components, such as conductor tracks, solder pads, etc., can be reliably attached and/or processed. Furthermore, the materials mentioned have proven to be particularly stable and temperature-resistant in various areas of application and processing.

In a further aspect, the invention relates to a MEMS transducer which can be produced or is produced by a preferred embodiment of the method according to the invention.

The average person skilled in the art will recognize that technical features, definitions, advantages and preferred embodiments described for the method of producing a MEMS transducer according to the invention apply equally to the MEMS transducer which can be produced according to the invention, and vice versa.

The producible MEMS transducer is advantageously characterized, for example, by increased design freedom with regard to the design of the carrier and the attachment of the membrane to it. This is achieved in particular by completely removing the shaping component instead of retaining a substrate or the shaping component as a carrier, as is the case in the prior art. This enables separate positioning on any carrier, as explained above. Furthermore, the complete removal of the shaping component has the advantage that it is possible to produce particularly compact MEMS transducers.

The method steps for producing the MEMS transducer according to the invention therefore not only entail a particularly economical and process-efficient production process, but also result in an advantageous structural design of the MEMS transducer.

The method steps according to the invention have a direct effect on the structural properties of the MEMS transducer, such that a person skilled in the art can easily determine whether a produced MEMS transducer has been produced using the method according to the invention.

As defined by the step of completely removing the shaping component, the producible MEMS transducer is characterized by the absence of a shaping component material. In particular, there are no residual structures of a shaping component on the rear side which—as proposed in WO 2021/144400 A1, for example—act as a carrier.

Instead, the membrane is attached in particular to a separate carrier, wherein the membrane and carrier make contact on a front side of the vibratable membrane instead of on the rear side as proposed in WO 2021/144400 A1.

It is therefore preferable that separate components are used to ensure the geometry and support of the membrane. In particular, the shaping component is completely removed to produce the MEMS transducer. The membrane is mounted on a carrier for a holder as a separate component. Since there is no lateral limitation of an only partially removed shaping component for holding the membrane in the finished carrier, the complete removal of the shaping component according to the invention can also be identified on the produced MEMS transducer itself. In particular, the person skilled in the art clearly recognizes that the shaping component used to provide the membrane in meander form is no longer part of the MEMS transducer. In this respect, the MEMS transducer that can be produced using the method according to the invention can also be clearly distinguished by a person skilled in the art from MEMS transducers known, for example, from DE 10 2017 115923 A1, whose membranes were structured by providing a negative form, wherein side regions of the negative form form the carrier or holder of the membrane. For example, the person skilled in the art can distinguish whether a membrane was deposited on a carrier when the carrier was still part of a shaping component or negative form, or whether the membrane was attached to a carrier as a separate component, for example by means of a conductive process material.

In preferred embodiments, the invention therefore relates to a MEMS transducer for interacting with a volumetric flow of a fluid comprising
a carrier and
a membrane for generating or receiving pressure waves of the fluid in a vertical direction, which is held by the carrier,
   wherein the membrane exhibits a meander structure with vertical sections and horizontal sections, wherein the vertical sections are configured substantially parallel to the vertical direction and the horizontal sections connect the vertical sections to one another, wherein the membrane comprises at least one actuator layer of an actuator material and is in contact with at least one electrode, such that the vertical sections can be induced to vibrate horizontally by controlling the at least one electrode or such that an electrical signal can be generated at the at least one electrode when the vertical sections are induced to vibrate horizontally,
   characterized in that
the membrane is attached to the carrier on a front side. The front side preferably means the side of the membrane facing the fluid, i.e. the side in the direction of which pressure waves are generated by the membrane or from the direction of which pressure waves can be received.

In further preferred embodiments, the membrane is attached to the front side of a carrier, wherein the carrier exhibits a substantially continuous border such that the membrane can be positioned stably at end regions.

In further preferred embodiments, the carrier exhibits one or more openings which function as a sound inlet opening or sound outlet opening, depending on the application of the MEMS transducer as a MEMS microphone or as a MEMS loudspeaker, wherein a front side of the membrane preferably faces the sound inlet opening or sound outlet opening. A conductive process material, for example a conductive adhesive or conductive soldering material, is particularly preferred for a mechanical and electrical connection between the carrier and the membrane, which, as explained above, enables a particularly good acoustic closure and stable electrical contact. Not only the position of the carrier in relation to the membrane, but also the manner in which it is attached is therefore characteristic of a MEMS transducer that can be produced using the method according to the invention.

Preferably, the MEMS transducer is provided in a bottom-port configuration, i.e. one or more sound inlet or sound outlet openings are present on the carrier, wherein these are preferably positioned opposite a rear side of the membrane. Advantageously, the rear volume of bottom port configurations of a MEMS microphone or MEMS loudspeaker is larger than the front volume. A large volume of air in the rear volume makes it easier for the membrane to move under the influence of the sound waves. This in turn improves the performance of a MEMS loudspeaker or the sensitivity or signal-to-noise ratio of a MEMS microphone.

The aspects according to the invention will be explained in more detail below using examples, without being limited to these examples.

### FIGURES

### Brief Description of the Figures

FIG. 1 Comparison of preferred steps for providing a MEMS transducer with methods previously disclosed in the prior art

FIG. 2 Schematic representation of preferred steps for coating the shaping component with a membrane layer system

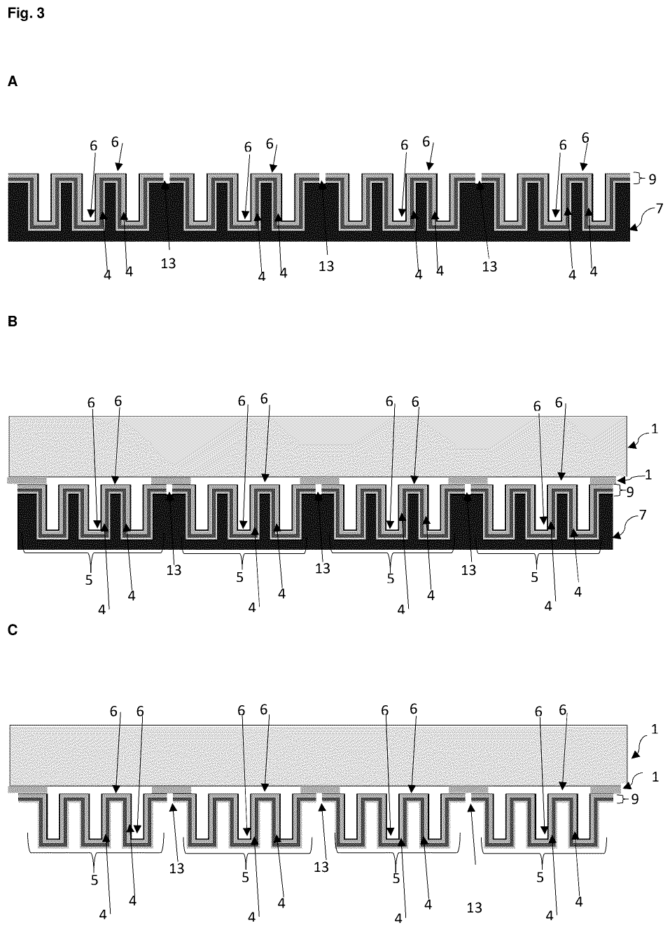

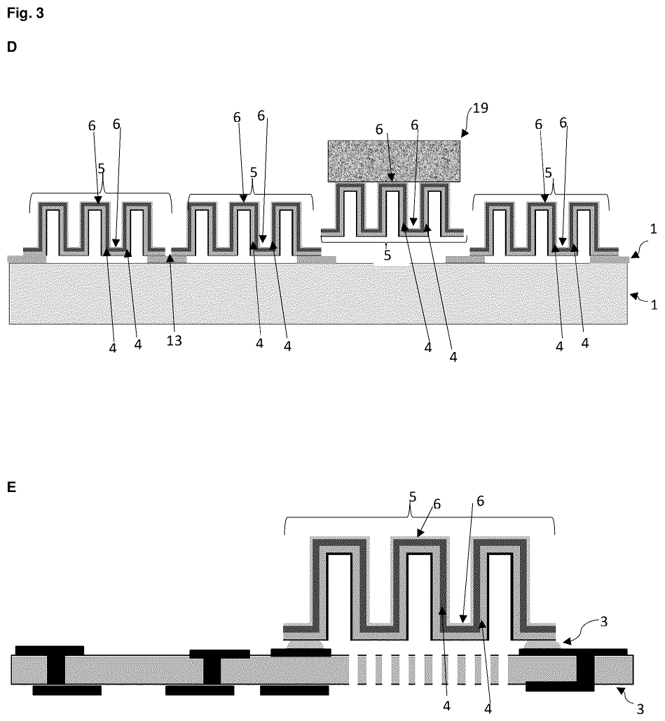

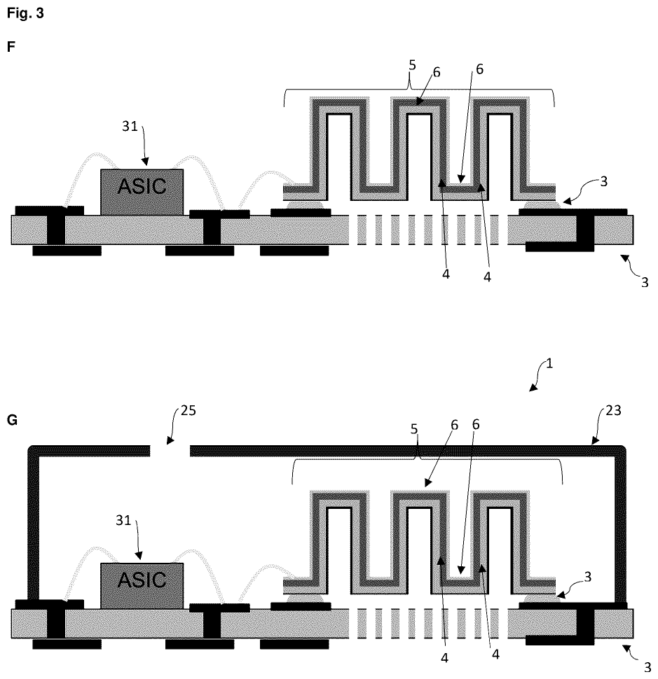

FIG. 3 Schematic representation of preferred method steps for further processing of a shaping component with a membrane layer system for producing a MEMS transducer using a support structure and mounting component

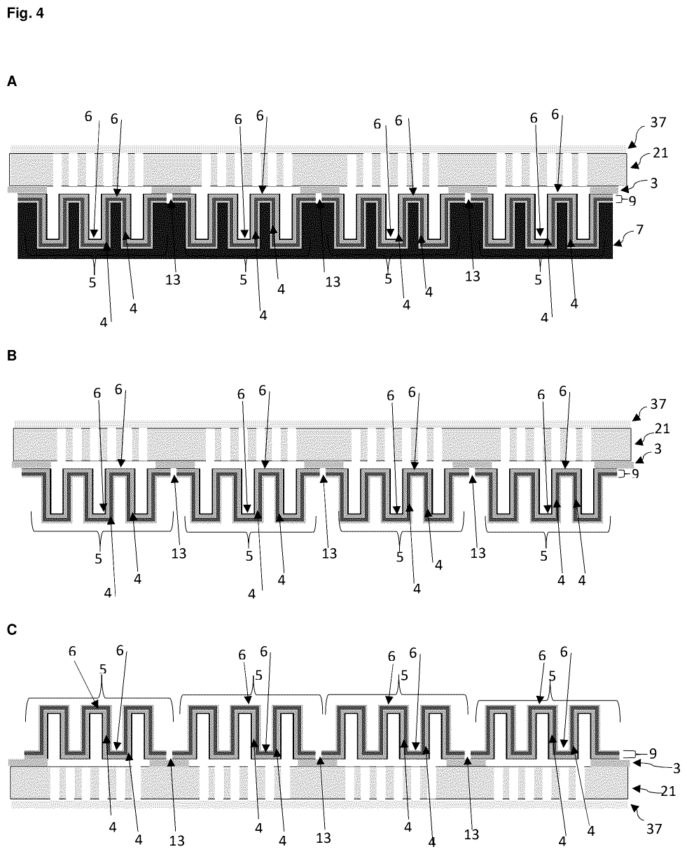

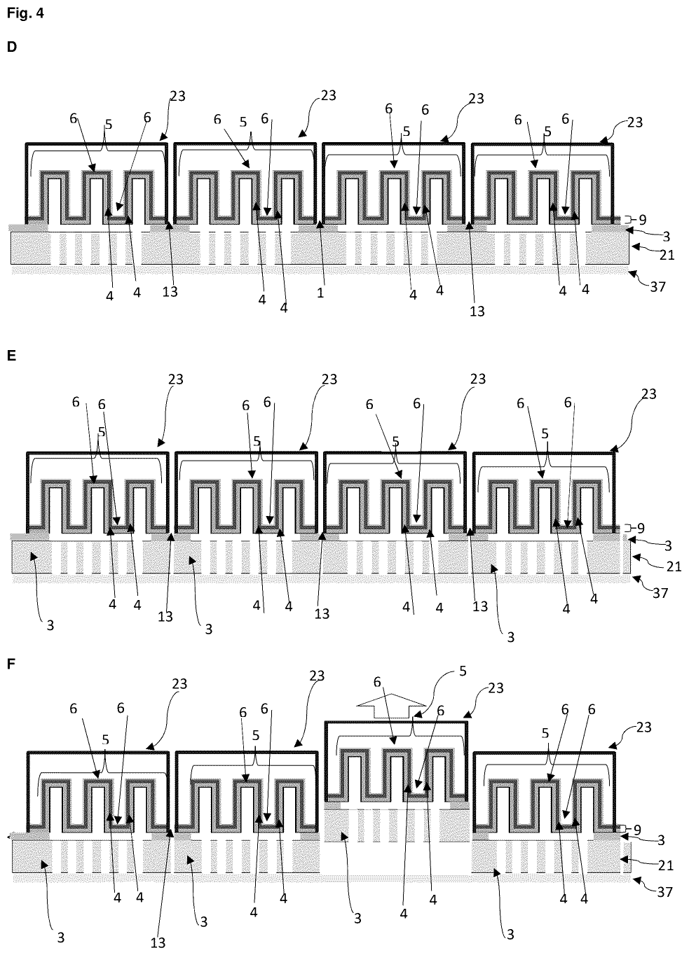

FIG. 4 Schematic representation of preferred method steps for the further processing of a shaping component with a membrane layer system for the production of a MEMS transducer with attachment of the membrane layer system to a support structure

### DETAILED DESCRIPTION OF THE FIGURES

FIG. 1 serves to illustrate a MEMS transducer and its production according to WO 2021/144400 A1 and a comparison of a MEMS transducer that can be produced using the preferred method.

FIG. 1A shows an example of a MEMS transducer from WO 2021/144400 A1. Here, the membrane 5 is held by a carrier region or a carrier 39, wherein the membrane 5 extends horizontally between side regions of the carrier region 39. The vertical direction for generating or receiving pressure waves, in particular sound waves, is orthogonal to the horizontal extension of the membrane 5. A housing is provided by a cover 23, wherein the front side of the membrane 5 is held opposite an opening on the carrier 39. The membrane 5 exhibits vertical sections 4, which are substantially parallel to the vertical direction and comprise at least one layer of an actuator material 11. The membrane 5 is in contact with an electrode at its end regions, such that the vertical sections 4 can be induced to vibrate horizontally and emit pressure waves by controlling the at least one electrode. Conversely, the vertical sections 4 can be induced to vibrate horizontally by pressure waves such that an electrical signal can be generated at the electrode.

Advantageously, an enlarged total volume can be moved in the vertical emission direction with small horizontal movements (displacements or curvatures) of a few micrometers due to the plurality of vertical sections 4 of the vibratable membrane 5 and thus used to generate sound. In the case of a MEMS loudspeaker, the configuration of the vibratable membrane 5 comprising vertical sections therefore entails increased sound power. In the case of a MEMS microphone, increased performance and audio quality with a suitable sound image is also achieved.

FIG. 1B and FIG. 1C illustrate known method steps for the production of such MEMS transducers.

After the membrane 5 has been coated onto a structured carrier substrate, the membrane 5 can be exposed by DRIE etching starting from a rear side (see FIG. 1B, right-hand image, arrows from below). In this case, edge regions of the carrier substrate remain as a carrier 39, between which the membrane 5 is suspended. However, the disadvantage of rear side DRIE etching is that it is time-consuming and cost-sensitive. In addition, DRIE etching is associated with restrictions with regard to the choice of sacrificial layers (stop oxides) and the possibility of achieving different depths during etching. In addition, process steps such as grinding and, in particular, dicing of the carrier substrate are required to provide a plurality of MEMS transducers.

In FIG. 1C, the rear side of the membrane 5 is exposed by means of KOH etching, wherein edge regions of the carrier substrate remain as a carrier 39, between which the membrane 5 is suspended. The increased size of the carrier 39 can be clearly seen, as a result of which the compactness of the MEMS transducer is compromised.

As illustrated in FIG. 1D, this also entails increased space requirements between the individual MEMS transducers when producing a plurality of MEMS transducers and therefore less efficient use of the wafer and increased costs.

FIG. 1E schematically illustrates the intended complete (rear side) removal of a shaping component or carrier substrate (bottom), which is in contrast to the previously illustrated methods in which edge regions of a structured substrate are left to act as a carrier 39 for the membrane 5 (top, crossed through).

FIG. 2 schematically shows preferred steps of the coating of the shaping component 7 with a membrane layer system 9. The membrane layer system 9 is coated on the shaping component 7 starting from a front side.

FIG. 2A shows the shaping component 7, which is initially provided before the coating of the membrane layer system 9 takes place. The shaping component 7 is provided here as a comb structure substrate 7 comprising comb fingers 43 and empty regions 45. The structure of the shaping component 7 (e.g. the length and/or width of the comb fingers 43 and/or empty regions 45) can be used to configure the meander structure of the membrane to be obtained. The shaping component 7 can be provided, for example, by means of a DRIE etching process or KOH etching.

FIG. 2B first shows the coating of a sacrificial layer 35 on the shaping component. The sacrificial layer 35 serves in particular to protect the membrane or the membrane layer system 9 during the removal of the shaping component 7, preferably by means of wet chemical etching. The sacrificial layer 35 can be TEOS or PECVD, for example.

As shown in FIG. 2C, a layer of a conductive material, which can act as a bottom electrode 29 for the membrane, is coated on the sacrificial layer 35. FIG. 2D then shows the coating of an actuator layer 11 comprising an actuator material, for example a piezoelectric material. Preferably, the piezoelectric material can exhibit a c-axis orientation perpendicular to the surface, wherein other orientations are also possible. FIG. 2E shows the coating of a further layer of an electrically conductive material to form a top electrode 27.

Thus, the membrane layer system 9 on the shaping component comprises a sacrificial layer 35, a bottom electrode 29, an actuator layer 11 and a top electrode 27. It is understood that the sacrificial layer 35 is preferably removed in the further production process of the MEMS transducer, such that the membrane 5 in the finished MEMS transducer exhibits a top layer as a top electrode 27, a middle layer as an actuator layer 11 and a bottom electrode 29. The bottom electrode 29 can preferably be formed from a conductive support material such that it also acts as a passive support layer.

FIG. 3 shows preferred method steps for further processing of the shaping component 7 with membrane layer system 9 according to FIG. 2 for producing a MEMS transducer using a support structure 17 and mounting component 19.

FIG. 3A shows the membrane layer system 9 on the shaping component 7. The membrane layer system exhibits vertical sections 4 and horizontal sections 6 after coating on the shaping component 7. Furthermore, FIG. 3A shows that the membrane layer system 9 can exhibit interruptions 13, wherein the interruptions 13 are formed by structuring the membrane layer system 9, in particular by lateral structuring. Consequently, a plurality of membranes 5 can be provided by means of a single shaping component 7. For this purpose, a membrane layer system 9 is first applied to the structured front side of the shaping component 7. To define the individual membrane 5, interruptions 13 are preferably formed by lateral structuring of the membrane layer system 9. As illustrated in FIG. 3A, the interruptions 13 are preferably formed on the comb fingers 43 and are thus present in the region of the horizontal sections 6 of the membrane 5, which connect the vertical sections 4 to one another at the upper or front end.

FIG. 3B illustrates a connection of the membrane layer system 9 after it has been structured by means of a detachable connection 15 to a support structure 17. The detachable connection can comprise an adhesive, for example a UV adhesive.

A connection to the support structure 17 can advantageously ensure the stability for the membranes 5 that is required after the complete removal of the shaping component 7.

Consequently, the support structure 17 advantageously ensures that the meander structure of the membranes 5 is maintained and the risk of loss of shape is reduced. Since the support structure 17 itself is not part of the MEMS transducer, but merely serves to temporarily stabilize the membranes 5, the support structure 17 can be selected from a cost perspective. The support structure 17 can, for example, be made of a flat plastic substrate or as a foil, preferably an adhesive foil.

A detachable connection 15 of the membranes 5 to the support structure 17 is used for the subsequent transfer of the membranes 5 to the carriers. The detachable connection 15 is preferably provided for this purpose in such a way that it is applied along the interruptions 13 of the membrane layer system 9 and thus the end regions of the individual membranes 5. The detachable connection is preferably a decomposable connection such that, starting from the membrane layer system 9, the membranes 5 can be removed free of any damage and thus reliably.

FIG. 3C shows the complete removal of the shaping component 7. The complete removal of the shaping component can preferably be carried out using a wet chemical etching process, in particular by KOH and/or TMAH etching. Advantageously, thin sacrificial layers 35 can be used and material can be saved by using wet chemical etching processes to completely remove the shaping component 7. In addition, due to the high selectivity of wet chemical etching processes, there is also a greater choice of material with regard to the sacrificial layers 35 than, for example, with a DRIE etching process.

FIG. 3D schematically illustrates a removal of the membrane 5 from the support structure 17 by a mounting component 19. The mounting component 17 can, for example, be configured to apply a low pressure such that the membrane 5 is detached from the detachable connection 15 or the support structure 17 by a pressure difference. A vacuum clamping device, a pressure needle and/or a pick-and-place tool can also be used as the mounting component 19.

The aforementioned options of the mounting component 19 have proven to be particularly reliable in order not to impair the shape of the filigree components of the membrane 5 during transportation from the support structure 17 to the carrier.

After removal of the membrane 5 using the mounting component 19, the membrane 5 is attached to a carrier 3 via a conductive process material 33, as shown in FIG. 3E. The carrier 3 is a structure which preferably exhibits a substantially continuous border such that the membrane 5 can be stably positioned at lateral end regions. Preferably, the carrier 3 exhibits one or more openings that function as sound inlet openings or sound outlet openings, depending on the application of the MEMS transducer as a MEMS microphone or as a MEMS loudspeaker. The conductive process material 33 serves as a stable connection between the carrier 3 and the membrane 5. Furthermore, the conductive process material 33 enables an acoustic closure and a possibility for electrical contact with an electronic circuit 31.

FIG. 3F shows that an electronic circuit 31 (here: “ASIC”) is preferably attached to the carrier 3. Depending on the use of the MEMS transducer, for example as a MEMS microphone or MEMS loudspeaker, the electronic circuit 31 is preferably configured to induce the membrane 5 to vibrate (and thus to generate sound waves) and/or to detect vibrations of the membrane 5 (due to excitation by incident sound waves).

The carrier 3 can then be connected to a cover 23, wherein the cover 23 exhibits a cover opening 25 (FIG. 1 G). By means of the cover 25, a solid and protective casing is applied to the MEMS transducer, in particular to protect components of the MEMS transducer 1. Thus, the cover 23 extends substantially over all components of the MEMS transducer, for example over the membrane 5, electrical connections and the electronic circuit 31. Furthermore, the dimensions of the cover 25 offer the possibility of configuring the rear volume of the MEMS transducer 1 with regard to the desired acoustic properties.

FIG. 4 shows preferred method steps for further processing of the shaping component 7 with membrane layer system 9 according to FIG. 2 to produce a MEMS transducer by attaching the membrane layer system 9 to a carrier structure 21.

FIG. 4A shows the connection of the membranes 5 or the membrane layer system 9 to a carrier structure 21. The connection between the membranes 5 and the carrier structure 21 can be realized by a conductive process material 33. Preferably, the carrier structure 21 is attached after the structuring of the membrane layer system 9 in order to form interruptions 13.

The carrier structure 21 preferably characterizes a structural preliminary stage for the provision of one or more carriers and can also be understood as an array of carrier elements, which are (still) contiguous in the carrier structure 21 and as a result of separation will form the carriers. For this purpose, the carrier structure 21 can already exhibit a number of structural components of a carrier, here for example a plurality of sound inlet or sound outlet openings. However, it may also be preferred that further processing steps follow the separation of the carrier structure 21

Preferably, the carrier structure 21 is characterized by sufficient stability to ensure that the meander structure of the membranes 5 is maintained during the complete removal of the shaping component 7. The shaping component is therefore preferably only completely removed after the carrier structure 21 is connected to the membrane layer system 9.

The carrier structure 21 is preferably attached after structuring of the membrane layer system 9 and thus separation of the membrane layer system 9 to form membranes 5 with the insertion of interruptions 13. The carrier structure 21 is preferably connected to the membrane layer system 9 at the position of the interruptions 13 of the membrane layer system 9, which correspond to the end regions of the membranes 5 to be formed, via a conductive process material 33.

It is also shown that a protective foil 37 is preferably provided on the carrier structure 21, wherein the protective foil 37 is present on the opposite side from the membrane layer system 9 and extends along the entire surface of the carrier structure 21. The protective foil 37 can provide protection for the carrier structure 21 or the carriers to be formed during different processing steps, such as removal of the shaping components 7 or sectional separation of the carrier structure 21 by dicing. The protective foil 37 can also define an end point for the dicing as a so-called dicing foil.

FIG. 4B illustrates the complete removal of the shaping component. FIG. 4C shows the same representation as in FIG. 4B, but in an inverted view to illustrate a possible further transport and/or positioning for the further processing steps.

FIG. 4D shows the connection of a plurality of covers 23 to the carrier structure 21. The connection is preferably made in such a way that the covers 23 are attached to the position of the interruptions 13 such that there is a precisely fitting cover 23 for each membrane 5.

FIG. 4E shows the regional separation of the carrier structure 21. The regional separation can be achieved by dicing, for example.

As illustrated in FIG. 4F, the MEMS transducers 1 can be removed from the protective foil and/or subjected to further processing after the carrier structure 21 has been regionally separated. A mounting component as described above can be used for this purpose.

### REFERENCE LIST

1 MEMS transducer
3 Carrier
4 Vertical section
5 Membrane
6 Horizontal section
7 Shaping component
9 Membrane layer system
11 Actuator layer
13 Interruption
15 Detachable connection
17 Support structure
19 Mounting component
21 Carrier structure
23 Cover
25 Cover opening
27 Top electrode
29 Bottom electrode
31 Electronic circuit
33 Conductive process material
35 Sacrificial layer
37 Protective foil
39 Rear side carrier or carrier region from the prior art
43 Comb fingers
45 Empty region

### BIBLIOGRAPHY

Kaiser B., Sergiu Langa, Lutz Ehrig, Michael Stolz, Hermann Schenk, Holger Conrad, Harald Schenk, Klaus Schimmanz and David Schuffenhauer, Concept and proof for an all-silicon MEMS microspeaker utilizing air chambers Microsystems & Nanoengineering volume 5, Article number: 43 (2019).
Shahosseini I., Elie LEFEUVRE, Johan Moulin, Marion Woytasik, Emile Martincic, et al. Electromagnetic MEMS Microspeaker for Portable Electronic Devices. Microsystem Technologies, Springer Verlag (Germany), 2013, pp. 10. <hal-01103612>.
Stoppel F., C. Eisermann, S. Gu-Stoppel, D. Kaden, T. Giese and B. Wagner, NOVEL MEMBRANE-LESS TWO-WAY MEMS LOUDSPEAKER BASED ON PIEZOELECTRIC DUAL-CONCENTRIC ACTUATORS, Transducers 2017, Kaohsiung, TAIWAN, Jun. 18-22, 2017.

1. A method for producing at least one MEMS transducer for interacting with a volume flow of a fluid comprising
a carrier and
a membrane for generating or receiving pressure waves of the fluid in a vertical direction, which is held by the carrier,
wherein the membrane exhibits a meander structure with vertical sections and horizontal sections, wherein the vertical sections are configured substantially parallel to the vertical direction and the horizontal sections connect the vertical sections to one another, wherein the membrane comprises at least one actuator layer made of an actuator material and is in contact with at least one electrode, such that the vertical sections can be induced to vibrate horizontally by controlling the at least one electrode or such that an electrical signal can be generated at the at least one electrode when the vertical sections are induced to vibrate horizontally, wherein the method comprises the following steps:
a) obtaining a shaping component,
b) coating of the shaping component with a membrane layer system comprising at least the actuator layer, wherein the membrane layer system, after coating on the shaping component, exhibits the meander structure comprising vertical sections and horizontal sections,
c) obtaining the membrane by structuring the membrane layer system, wherein by forming interruptions the membrane layer system is separated to provide the membrane,
d) completely removing the shaping component, and
e) attaching the membrane to the carrier such that the membrane is held by the carrier.

2. The method according to claim 1, wherein a plurality of MEMS transducers are produced, wherein the membrane layer system is structured on the shaping component (7) to form individual membranes in order to produce the plurality of MEMS transducers.

3. The method according to claim 1, wherein the shaping component is provided by an application of a dry etching process and/or a wet chemical etching process to a substrate.

4. The method according to claim 1, wherein the shaping component is completely removed by a wet chemical etching process, a dry etching process and/or a vapor etching process.

5. The method according to claim 1, wherein after the structuring of the membrane layer system, a plurality of membranes are connected to a support structure by means of a detachable connection.

6. The method according to claim 1, wherein the membrane (5) is removed from a support structure by a mounting component.

7. The method according to claim 1, wherein the membrane is attached to the carrier via a conductive process material.

8. The method according to claim 1, wherein the carrier is connected to a cover.

9. The method according to claim 1, wherein after the structuring of the membrane layer system, a plurality of membranes are connected to a support structure and the shaping component is then completely removed.

10. The method according to claim 1, wherein after the complete removal of the shaping component, a carrier structure is regionally separated such that, starting from the carrier structure, a plurality of carriers are provided and a membrane is attached to one of the plurality of carriers in each case.

11. The method according to claim 1, wherein a carrier structure is connected to a plurality of covers.

12. The method according to claim 1, wherein the membrane comprises at least two layers, wherein both layers comprise an actuator material and are respectively in contact with an electrode, and the horizontal vibrations can be generated by a change in shape of one layer relative to the other, or the horizontal vibrations lead to a change in shape of one layer relative to the other layer and generate an electrical signal.

13. The method according to claim 1, wherein the membrane comprises at least two layers, wherein a first layer comprises an actuator material and a second layer comprises a mechanical support material, wherein at least the first layer comprising the actuator material is in contact with the electrode, such that horizontal vibrations can be generated by a change in shape of the actuator material relative to the mechanical support material or such that horizontal vibrations lead to a change in shape of the actuator material in relation to the mechanical support material and generate an electrical signal.

14. The method according to claim 1, wherein the membrane comprises three layers, wherein an upper layer is formed by a conductive material and functions as a top electrode, a middle layer is formed by an actuator material and a lower layer is formed by a conductive material and functions as a bottom electrode.

15. A MEMS transducer producible by a method according to claim 1.

16. The method of claim 2, wherein the individual membranes are separated by interruptions.

17. The method of claim 16, wherein the interruptions are formed as a whole after the coating of the membrane layer system or layer by layer.

18. The method of claim 3, wherein the dry etching process is a physical, a chemical and/or a physico-chemical dry etching process.

19. The method of claim 18, wherein particularly the dry etching process is selected from a group comprising reactive ion etching (RIE) and/or deep reactive ion etching (DRIE).

20. The method of claim 3, wherein KOH etching is used as the wet chemical etching process.
